(19) United States
(12) Patent Application Publication
(10) Pub. No.: US 2009/0109628 A1
(43) Pub. Date: Apr. 30, 2009

(54) Chip Cooling System with Convex Portion

(75) Inventors: Raschid J. Bezama, Mahopac, NY (US); James N. Humenik, LaGrangeville, NY (US); Sushumna Iruvanti, Wappingers Falls, NY (US); Govindarajan Natarajan, Poughkeepsie, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/928,165

(22) Filed: Oct. 30, 2007

(51) Int. Cl. H01L 23/367; F28F 7/00

(52) U.S. Cl. 361/707; 165/80.2; 257/711; 361/704; 257/E23.102

(57) ABSTRACT

Integrated circuit chip cooling methods and systems are disclosed. A method for cooling an integrated circuit chip may comprise: providing a cooling mechanism; positioning an interface medium between the cooling mechanism and the integrated circuit chip; and interfacing the cooling mechanism and the integrated circuit chip through the interface medium; wherein at least one of the cooling mechanism, the integrated circuit chip, or the interface medium includes a convex portion on an interface surface thereof.

### BACKGROUND

1. Technical Field

The disclosure relates generally to integrated circuit (IC) chip, and more particularly, to cooling an IC chip with a cooling system including convex portions in an interface surface.

2. Background Art

The capability to cool an integrated circuit (IC) chip, e.g., a high power microprocessor chip, is increasingly dependent on the thermal-mechanical characteristics of thermal interface material (TIM) used between the IC chip and the cooling assembly. An ideal TIM needs to be mechanically compliant to decouple mechanical stresses between the IC chip and the cooling assembly and to satisfy a given level of stress testing. The TIM also needs to have low thermal resistance, preferably lower than that of the cooling assembly.

### SUMMARY

A first aspect of the disclosure provides a method for cooling an integrated circuit chip comprising: providing a cooling mechanism; positioning an interface medium between the cooling mechanism and the integrated circuit chip; and interfacing the cooling mechanism and the integrated circuit chip through the interface medium; wherein at least one of the cooling mechanism, the integrated circuit chip, or the interface medium includes a convex portion on an interface surface thereof.

A second aspect of the disclosure provides an interface medium for interfacing between a cooling mechanism and a cooling target, the interface medium comprising: an array of convex portions on an interface surface.

A third aspect of the disclosure provides a cooling system comprising: a cooling mechanism including an array of convex portions on an interface surface; and an interface medium capable of being deformed by the convex portions.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows one embodiment of an IC chip cooling system according to the disclosure.

FIG. 2 shows another embodiment of an IC chip cooling system according to the disclosure.

FIG. 3 shows an embodiment of an interface medium according to the disclosure.

FIGS. 4-5 show embodiments of a pattern of convex portion array.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

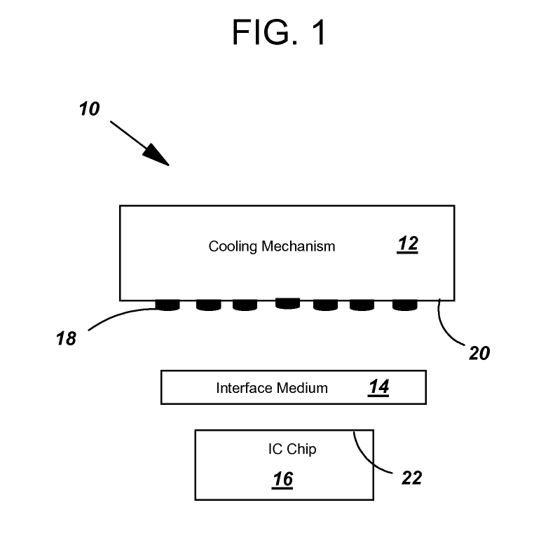

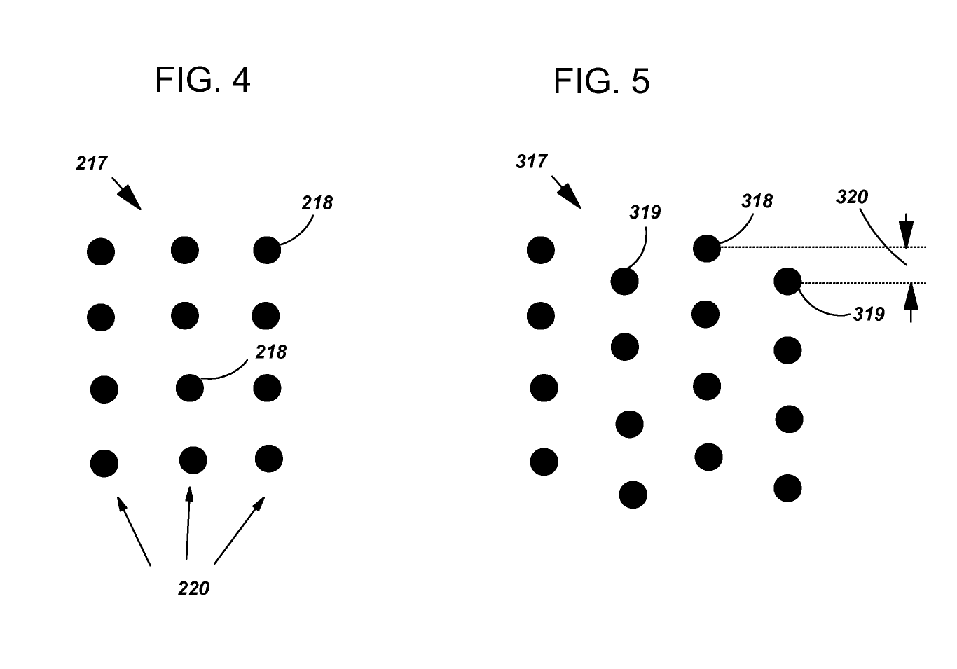

Referring to FIG. 1, one embodiment of an integrated circuit (IC) chip cooling system 10 according to the disclosure is shown. Cooling system 10 includes a cooling mechanism 12 and an interface medium 14 positioned between cooling mechanism 12 and an IC chip 16 (i.e., cooling target). Cooling mechanism 12 includes an array of convex portions 18 on an interface surface 20 of cooling mechanism 12 which may interface with IC chip 16 through interface medium 14 in a cooling operation. Interface medium 14 may be of any now known or later developed TIM material provided that interface medium 14 is capable of being deformed by convex portion 18 such that when cooling mechanism 12 and an interface surface 22 of IC chip 16 interface with one another through interface medium 14, interface medium 14 may be deformed according to a pattern of convex portions 18 (shown in FIGS. 4-5) to, e.g., reduce and or eliminate air gap(s) between IC chip surface 22 and interface medium 14 and/or between interface medium 14 and cooling mechanism 12. In the description, the term “interface” refers to positioning two or more surfaces together such that the surfaces directly or indirectly contact one another.

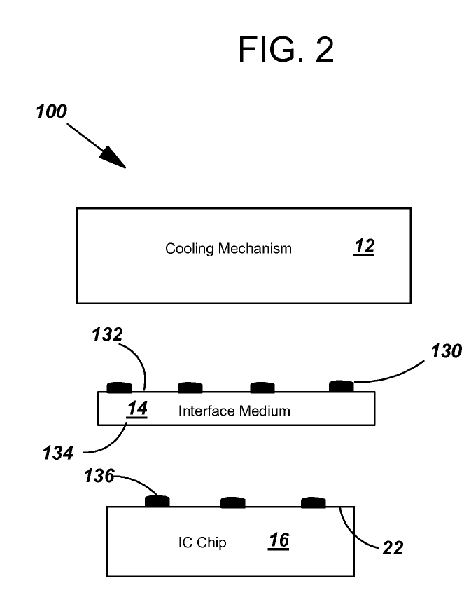

According to another embodiment, as shown in cooling system 100 of FIG. 2, interface medium 14 includes (an array of) convex portions 130 on an interface surface 132. FIG. 2 shows that interface medium 14 includes convex portions 130 only on interface surface 132 facing cooling mechanism 12. Interface medium 14 may include convex portions 130 on interface surface 134 facing IC chip 16 or on both interface surfaces 132 and 134.

As shown in FIG. 2, IC chip 16 may also include (an array of) convex portions 136 on interface surface 22. According to an embodiment, convex portions, e.g., 130, 136, which are on different interface surfaces, e.g., interface surfaces 132, 22, respectively, misalign by a prescribed location geometry with respect to one another. That is, a convex portion 130 will not press on a convex portion 136 in the interfacing between cooling mechanism 12 and IC chip 16.

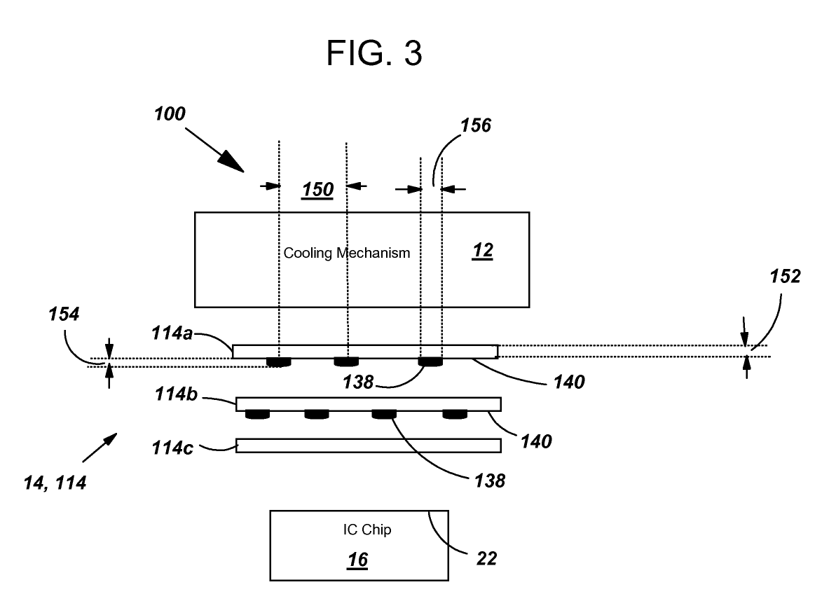

Referring to FIG. 3, according to an embodiment, interface medium 14 may include multiple layers 114 (three shown with referrals 114a, 114b, 114c). At least one of interface layers 114 (here 114a and 114b, for illustration) may include convex portions 138 on an interface surface 140 thereof facing another interface layer 114. Convex portions 138 on different interface surfaces 140 misalign by a prescribed location geometry as described above. According to an embodiment, a layer 114 may be a metal foil, preferably gold or silver, and convex portions 138 may be for example metal bumps with prescribed shape geometry. Preferably, the thermal conductivity of a metal foil 114 is greater than approximately 20 W/m K and the thermal conductivity of a metal bump 138 is greater than approximately 1 W/m K. It should be appreciated that interface medium 14 and/or interface layer 114 may be made of other materials. In addition, different interface layer 114 may be of different materials.

Convex portions in the embodiments of FIGS. 1-3 may be arranged in an array. Here the term “array” includes the situation of multiple arrays. A specific case of multiple arrays is a matrix, i.e., rows and columns of varying location geometry. A pattern of the convex portion array refers to a relative position of a given convex portion relative to adjacent convex portions in the array. For example, FIG. 4 shows a pattern 217 where convex portions 218 in all arrays 220 align with one another. FIG. 5 shows another pattern 317 where each convex portion 318 misaligns with adjacent convex portions 319 in a different array by a prescribed distance 320. Prescribed distance 320 is shown as an example of the interstitial geometry. It should be appreciated any pattern of convex portion array is possible and included.

The disclosure also includes a method for cooling IC chip 16. Cooling mechanism 12 may be positioned to interface with IC chip 16 through interface medium 14 to cool off IC chip 16. In implementing the method, all embodiments shown in FIGS. 1-5 may be used separately or in various combinations.

A parameter of the convex portions, e.g., convex portions 138 of FIG. 3, and/or a parameter of a convex portion array may be determined based on at least one of: a surface typography of IC chip 16, a geometry, i.e., dimensions (length, width and thickness), of interface medium 14, a mechanical characteristic (e.g., elasticity) of interface medium 14, or a thermal conductivity of interface medium 14 and/or convex portion 138. The parameter of a convex portion, e.g., convex portion 138, may include a height, hardness and convex portion aspect ratio thereof. The parameter of a convex portion array may include a density, a pattern and an array aspect ratio thereof. A density of convex portion array refers to the number of convex portions within a unit surface area of the respective interface surface. The parameters of convex portions and convex portion arrays are determined such that when cooling mechanism 12 interfaces with IC chip 16 through interface medium 14, air gaps are minimized therebetween and thereamong.

For example, an array aspect ratio defined as a distance 150 between two immediately adjacent convex portions 138 divided by a thickness 152 of layer (foil) 114 (FIG. 3) is preferably less than approximately 10. According to an embodiment, thickness 152 of foil 114 may be determined approximately using formula:

Thickness [in meter]=Square root of [Pressure applied on convex portion 138/(300 times elasticity of foil 114)]

A convex portion aspect ratio (defined as height 154 of convex portion 138 divided by diameter 156 of convex portion 138 at the bottom abutting the respective layer 114) is determined based on thermal resistance of convex portion 138 which is preferably less than 2 mm² K/W. Hardness of a convex portion 18 (FIG. 1) may be chosen to deform the TIM material of interface medium 14. Height of a convex portion 18 may be chosen based on a surface flatness of IC chip 16. Pattern of convex array may be chosen based on a pattern of surface flatness and/or unevenness of IC chip 16.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method for cooling an integrated circuit chip comprising:
providing a cooling mechanism;
positioning an interface medium between the cooling mechanism and the integrated circuit chip; and
interfacing the cooling mechanism and the integrated circuit chip through the interface medium;
wherein at least one of the cooling mechanism, the integrated circuit chip, or the interface medium includes a convex portion on an interface surface thereof.

2. The method of claim 1, wherein the interface medium includes multiple layers and at least one of the layers includes a convex portion on an interface surface thereof facing another layer.

3. The method of claim 1, wherein the convex portion includes an array of multiple convex portions

4. The method of claim 3, further comprising determining a parameter of the convex portion array and each of the multiple convex portions based on at least one of: a surface typography of the integrated circuit chip, a geometry of the interface medium, a mechanical characteristic of the interface medium, a thermal conductivity of the interface medium, or a thermal conductivity of the convex portion.

5. The method of claim 4, wherein the parameter of the convex portion includes a height, hardness or an aspect ratio thereof.

6. The method of claim 4, wherein a parameter of the convex portion array includes a density, an array aspect ratio thereof.

7. The method of claim 4, wherein a parameter of the convex portion array includes a pattern of a relative position between a convex portion and adjacent convex portions in the array.

8. The method of claim 1, wherein convex portions on different interface surfaces misalign.

9. An interface medium for interfacing between a cooling mechanism and a cooling target, the interface medium comprising:
an array of convex portions on an interface surface.

10. The interface medium of claim 8, further comprising multiple interface layers, at least one of the interface layers including a convex portion on an interface surface thereof facing another interface layer.

11. The interface medium of claim 8, wherein the interface medium includes a metal foil and metal convex portions.

12. The interface medium of claim 10, wherein the an array aspect ratio of the metal convex portions is preferably less than approximately 10, the array aspect ratio being defined as a distance between two immediately adjacent convex portions divided by a thickness of the metal foil, and the thickness being determined approximately using formula:
Thickness [in meter]=Square root of [Pressure applied on the convex portion/(300 times an elasticity of the metal foil)].

13. The interface medium of claim 10, wherein an aspect ratio of the metal convex portion is determined based on a thermal resistance of the metal convex portion, the aspect ratio being a height of the metal convex portion divided by a diameter of the metal convex portion at a bottom.

14. A cooling system comprising:
a cooling mechanism including an array of convex portions on an interface surface; and
an interface medium capable of being deformed by the convex portions.
